(19) United States
(12) Patent Application Publication
(10) Pub. No.: US 2025/0140752 A1
(43) Pub. Date: May 1, 2025

(54) SEMICONDUCTOR PACKAGE

(71) Applicant: SAMSUNG ELECTRONICS CO., LTD., Suwon-si (KR)

(72) Inventor: YOUNGBAE KIM, Suwon-si (KR)

(73) Assignee: SAMSUNG ELECTRONICS CO., LTD., Suwon-si (KR)

(21) Appl. No.: 18/737,442

(22) Filed: Jun. 7, 2024

(30) Foreign Application Priority Data
Oct. 27, 2023 (KR) 10-2023-0145368

(51) Int. Cl. H01L 25/065; H01L 23/00; H01L 23/31; H01L 23/498; H01L 23/522; H01L 25/10; H10B 12/00; H10B 80/00

(52) U.S. Cl. CPC H01L 25/0657; H01L 23/3107; H01L 23/49838; H01L 23/5223; H01L 24/08; H01L 25/105; H10B 80/00; H10D 1/692; H01L 2224/08145; H01L 2225/06541; H01L 2225/06555; H01L 2924/1431; H01L 2924/1436; H10B 12/315

(57) ABSTRACT

A semiconductor package is provided that includes a buffer chip, a plurality of semiconductor chips on the buffer chip, and a molding layer on the buffer chip and the plurality of semiconductor chips. The buffer chip includes a device layer and a capacitor layer on the device layer. The device layer includes a plurality of transistors that constitute logic circuits. The capacitor layer includes at least one capacitor. The plurality of semiconductor chips vertically overlap the capacitor.

### CROSS-REFERENCE TO RELATED APPLICATION

This U.S. non-provisional application claims priority under 35 U.S.C § 119 to Korean Patent Application No. 10-2023-0145368, filed on Oct. 27, 2023, in the Korean Intellectual Property Office, the disclosure of which is hereby incorporated by reference in its entirety.

### BACKGROUND

### 1. Technical Field

Embodiments of the present disclosure relate to a semiconductor package, and more particularly, to a semiconductor package whose electrical properties are increased and whose size is reduced.

### 2. Brief Description of Related Art

In the semiconductor industry, semiconductor devices that have high capacity, thinness, and a small size, and electronic products using the same, have been demanded and thus various package techniques have been suggested. A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of the electronic industry, electronic products have increasingly required high performance, high speed, and compact size.

### SUMMARY

Some embodiments of the present disclosure provide a semiconductor package with improved electrical properties and reduced size.

According to embodiments of the present disclosure, a semiconductor package is provided and includes: a buffer chip; a plurality of semiconductor chips stacked on the buffer chip; and a molding layer on the buffer chip and the plurality of semiconductor chips, wherein the buffer chip includes a device layer and a capacitor layer on the device layer, wherein the device layer includes a plurality of transistors that constitute logic circuits, wherein the capacitor layer includes a capacitor, and wherein the plurality of semiconductor chips vertically overlap the capacitor.

According to embodiments of the present disclosure, a semiconductor package is provided and includes: a buffer chip that includes a device layer and a capacitor layer on the device layer; and a memory chip that includes a wiring layer and a core layer on the wiring layer, wherein the device layer includes a plurality of transistors that constitute a logic circuit, wherein the capacitor layer includes a capacitor and an upper pad, wherein the wiring layer includes a front pad connected to the upper pad, wherein the core layer includes a memory device electrically connected to the capacitor through the upper pad and the front pad, and wherein the capacitor vertically overlaps with the memory chip.

According to embodiments of the present disclosure, a semiconductor package is provided and includes: an interposer substrate; a logic chip on the interposer substrate; and at least one chip stack on the interposer substrate and spaced apart from the logic chip, wherein the interposer substrate includes: a lower wiring layer that includes a plurality of lower pads and a plurality of lower wiring patterns; an upper wiring layer that includes a plurality of upper pads and a plurality of upper wiring patterns; and a first capacitor layer between the lower wiring layer and the upper wiring layer, wherein the first capacitor layer includes at least one first capacitor, wherein the at least one first capacitor vertically overlaps at least one from among the logic chip and the at least one chip stack, and wherein the at least one first capacitor is electrically connected through the plurality of upper pads and the plurality of upper wiring patterns to at least one from among the logic chip and the at least one chip stack.

Aspects of the present disclosure are not limited to the aspects mentioned above, and other aspects which have not been mentioned above will be clearly understood to those skilled in the art from the following description.

### BRIEF DESCRIPTION OF DRAWINGS

FIG. 1 illustrates a cross-sectional view showing a semiconductor package according to some embodiments of the present disclosure.

FIG. 2A illustrates an enlarged view of section P1 depicted in FIG. 1, partially showing a semiconductor package according to some embodiments of the present disclosure.

FIG. 2B illustrates an enlarged view of section P1 depicted in FIG. 1, partially showing a semiconductor package according to some embodiments of the present disclosure

FIG. 3 illustrates a plan view showing a semiconductor package according to some embodiments of the present disclosure.

FIG. 4 illustrates a cross-sectional view taken along line A-A′ of FIG. 3, showing a semiconductor package according to some embodiments of the present disclosure.

FIG. 5 illustrates an enlarged view of section P2 depicted in FIG. 4, partially showing a semiconductor package according to some embodiments of the present disclosure.

### DETAILED DESCRIPTION

The following will now describe some non-limiting example embodiments of the present disclosure with reference to the accompanying drawings. Like reference numerals may indicate like components throughout the description.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

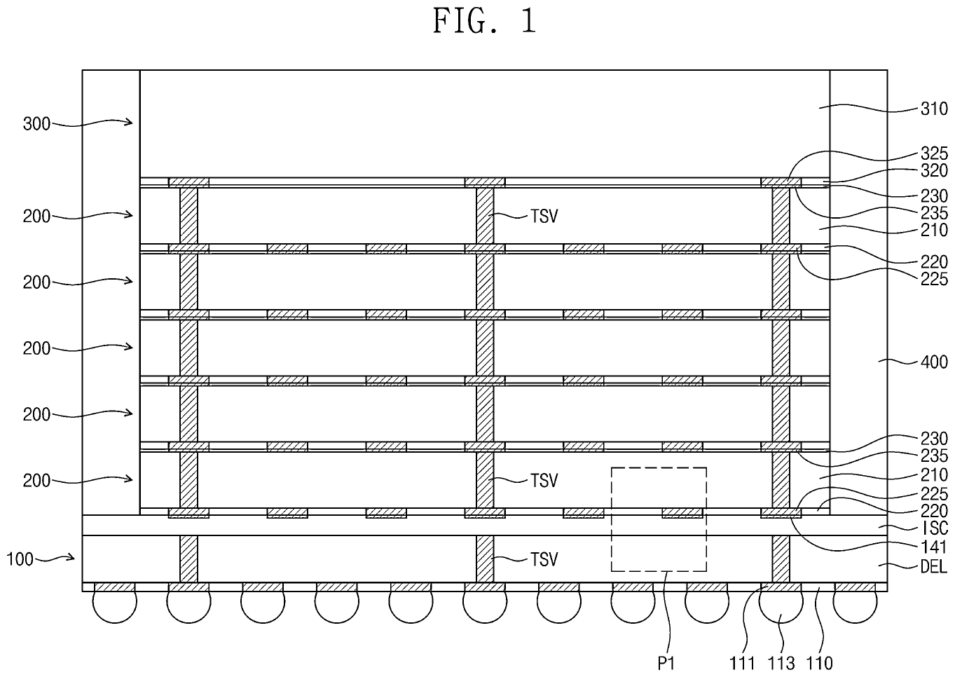

FIG. 1 illustrates a cross-sectional view showing a semiconductor package according to some embodiments of the present disclosure.

Referring to FIG. 1, a semiconductor package may be provided. The semiconductor package may include a buffer chip 100, first semiconductor chips 200, a second semiconductor chip 300, and a molding layer 400. The semiconductor package may be a stacked memory package in which through vias TSV are used. For example, the semiconductor package may be a high bandwidth memory (HBM), but embodiments of the present disclosure are not limited thereto.

The buffer chip 100 may be positioned in a lower portion of the semiconductor package. The buffer chip 100 may include a substrate protection layer 110, a device layer DEL on the substrate protection layer 110, and a capacitor layer ISC on the device layer DEL. For example, the buffer chip 100 may be a wafer-level die formed of a semiconductor such as silicon, but embodiments of the present disclosure are not limited thereto.

The substrate protection layer 110 may be positioned on a bottom surface of the device layer DEL. The substrate protection layer 110 may cover the device layer DEL. For example, the substrate protection layer 110 may include silicon oxide (SiO), silicon nitride (SiN), silicon oxynitride (SiON), or silicon carbonitride (SiCN).

The substrate protection layer 110 may include lower pads 111 therein. The lower pads 111 may be exposed by a bottom surface of the substrate protection layer 110. The substrate protection layer 110 may surround lateral surfaces of the lower pads 111. For example, the lower pads 111 may have their bottom surfaces coplanar with the bottom surface of the substrate protection layer 110. As the lower pads 111 are spaced apart from each other in a horizontal direction, the lower pads 111 may be located on the same level. The lower pads 111 may include a metallic material, such as copper (Cu), aluminum (Al), and/or nickel (Ni).

The substrate protection layer 110 may be provided with connection terminals 113 on the bottom surface thereof. The connection terminals 113 may be positioned on corresponding bottom surfaces of the lower pads 111. The buffer chip 100 may be electrically connected through the connection terminals 113 to an external electronic apparatus or another semiconductor package. For example, the connection terminals 113 may each be an alloy that includes at least one from among silver (Ag), copper (Cu), nickel (Ni), bismuth (Bi), indium (In), antimony (Sb), and cerium (Ce).

The device layer DEL may be positioned between the substrate protection layer 110 and the capacitor layer ISC. The device layer DEL may include an integrated circuit therein. The integrated circuit may be formed of a plurality of transistors. For example, the integrated circuit layer may be a memory circuit, a logic circuit, or a combination thereof.

The through vias TSV may penetrate in a vertical direction through a portion of the buffer chip 100. For example, the through vias TSV may penetrate the device layer DEL of the buffer chip 100. The through vias TSV may penetrate the device layer DEL to electrically connect the lower pads 111 to the capacitor layer ISC. The through vias TSV may be connected to the integrated circuit of the device layer DEL. For example, the through vias TSV may include at least one metal from among aluminum (Al), copper (Cu), tungsten (W), molybdenum (Mo), and cobalt (Co).

The capacitor layer ISC may include therein upper pads 141 and at least one capacitor. The capacitor may be electrically connected to the upper pads 141. The capacitor may be electrically connected to the through vias TSV or the integrated circuit of the device layer DEL.

The upper pads 141 may be positioned at a top surface of the capacitor layer ISC. The upper pads 141 may be spaced apart from each other in the horizontal direction. For example, the upper pads 141 may be located at the same level as each other. The upper pads 141 may be exposed by the capacitor layer ISC. The upper pads 141 may have their top surfaces coplanar with the top surface of the capacitor layer ISC. For example, the upper pads 141 may include a metallic material, such as copper (Cu), aluminum (Al), and/or nickel (Ni).

A plurality of first semiconductor chips 200 may be positioned on the buffer chip 100. The first semiconductor chips 200 may be stacked in the vertical direction. For example, the first semiconductor chips 200 may vertically overlap each other, and may be located at different levels. The first semiconductor chips 200 may have substantially the same width as each other in the horizontal direction. The width in the horizontal direction of each of the first semiconductor chips 200 may be less than a width in the horizontal direction of the buffer chip 100. Thus, a top surface of the buffer chip 100 may be partially exposed.

Each of the first semiconductor chips 200 may include a first wiring layer 220, a first core layer 210, and a first protection layer 230. The first wiring layer 220, the first core layer 210, and the first protection layer 230 may be sequentially stacked. For example, the first semiconductor chips 200 may be memory chips having the same structure as each other.

The first wiring layer 220 may be positioned on a bottom surface of the first core layer 210. The first wiring layer 220 may include an integrated circuit and first front pads 225. The first front pads 225 may be positioned at a bottom surface of the first wiring layer 220. The first front pads 225 may be exposed by the first wiring layer 220. For example, the first front pads 225 may have their bottom surfaces coplanar with the bottom surface of the first wiring layer 220. The integrated circuit may be a memory circuit.

The first core layer 210 may be positioned between the first wiring layer 220 and the first protection layer 230. The first core layer 210 may include semiconductor devices integrated on a semiconductor substrate, and may also include through vias TSV. Each of the through vias TSV may penetrate the first core layer 210. The through vias TSV may be connected to corresponding first front pads 225 of the first wiring layer 220. For example, the semiconductor devices may include a memory device.

The first protection layer 230 may be positioned on the first core layer 210. The first protection layer 230 may include first backside pads 235 therein. The first backside pads 235 may be positioned at a top surface of the first protection layer 230. The first backside pads 235 may be exposed by the first protection layer 230. For example, the first backside pads 235 may have their top surfaces coplanar with the top surface of the first protection layer 230. The first backside pads 235 may be connected to corresponding through vias TSV of the first core layer 210.

As the first front pads 225 and the first backside pads 235 are connected to the through vias TSV, the first front pads 225 may be electrically connected via the through vias TSV to the first backside pads 235. The first front pads 225, the first backside pad 235, and the through vias TSV that are electrically connected may vertically overlap each other, but embodiments of the present disclosure are not limited thereto. The first front pads 225, the first backside pad 235, and the through vias TSV may include, for example, a metallic material, such as copper (Cu), aluminum (Al), and/or nickel (Ni).

The second semiconductor chip 300 may be positioned on the first semiconductor chips 200. The second semiconductor chip 300 may be a semiconductor chip positioned at an uppermost end in the semiconductor package. For example, the second semiconductor chip 300 may be a memory chip as like the first semiconductor chip 200, but may not have the same structure as a structure of the first semiconductor chip 200. The second semiconductor chip 300 may include a second wiring layer 320 and a second core layer 310.

The second wiring layer 320 may be positioned on an uppermost one of the first semiconductor chips 200. The second wiring layer 320 may include second front pads 325 therein. The second front pads 325 may be positioned at a bottom surface of the second wiring layer 320. The second front pads 325 may be exposed by the second wiring layer 320. For example, the second front pads 325 may have their bottom surfaces coplanar with the bottom surface of the second wiring layer 320.

The second core layer 310 may be positioned on the second wiring layer 320. The second core layer 310 may include a semiconductor device therein. Unlike the first core layer 210, the second core layer 310 may not include the through vias TSV.

The semiconductor package according to an embodiment of the present disclosure may include semiconductor chips mounted in a direct bonding manner. For example, the buffer chip 100 may be in contact with a lowermost one of the first semiconductor chips 200. The upper pads 141 of the buffer chip 100 may be correspondingly in contact with the first front pads 225 of the lowermost one of the first semiconductor chips 200. The upper pads 141 may vertically overlap the first front pads 225 with which the upper pads 141 are in contact.

A hybrid bonding may be provided between the upper pads 141 and the first front pads 225 that are in contact with each other. In this description, the term “hybrid bonding” may denote a bonding in which two components of the same kind are merged at an interface therebetween. For example, the upper pad 141 and the first front pad 225 that are in contact with each other may be combined into a single object, and an invisible interface may be present between the upper pad 141 and the first front pad 225.

The first semiconductor chips 200 may be stacked while being in contact with each other. For example, the first protection layer 230 of one of the first semiconductor chips 200 may be in contact with the first wiring layer 220 of another one of the first semiconductor chips 200 that is adjacent in the vertical direction to the one of the first semiconductor chips 200. Thus, the first backside pads 235 of the first protection layer 230 may be in contact with corresponding first front pads 225 of the first wiring layer 220. The first backside pad 235 and the first front pad 225 that are in contact with each other may vertically overlap each other. For example, a hybrid bonding may be achieved between the first backside pad 235 and the first front pad 225 that are in contact with each other.

In addition, the uppermost one of the first semiconductor chips 200 may be in contact with the second semiconductor chip 300. The first protection layer 230 of the uppermost one of the first semiconductor chips 200 may be in contact with the second wiring layer 320 of the second semiconductor chip 300. The first backside pads 235 of the first protection layer 230 included in the uppermost one of the first semiconductor chips 200 may be in contact with corresponding second front pads 325 of the second wiring layer 320. The first backside pads 235 and the second front pads 325 that are in contact with each other may vertically overlap each other. For example, a hybrid bonding may be achieved between the first backside pads 235 and the second front pads 325 that are in contact with each other.

A solder ball or a solder bump may be omitted between the buffer chip 100 and the lowermost one of the first semiconductor chips 200, between the first semiconductor chips 200, and between the uppermost one of the first semiconductor chips 200 and the second semiconductor chip 300. The semiconductor package may accordingly become compact-sized.

The molding layer 400 may be provided on the buffer chip 100. The molding layer 400 may cover the top surface of the buffer chip 100 exposed by the lowermost one of the first semiconductor chips 200. A lateral surface of the molding layer 400 may be aligned with lateral surfaces of the buffer chip 100. The molding layer 400 may surround the first semiconductor chips 200 and the second semiconductor chip 300. For example, the molding layer 400 may cover lateral surfaces of the first semiconductor chips 200 and the second semiconductor chip 300. A top surface of the molding layer 400 may be coplanar with the top surface of the second semiconductor chip 300, and thus the top surface of the second semiconductor chip 300 may be exposed by the molding layer 400. Embodiments of the present disclosure, however, are not limited thereto, and the molding layer 400 may cover the top surface of the second semiconductor chip 300. The molding layer 400 may include, for example, an epoxy molding compound (EMC).

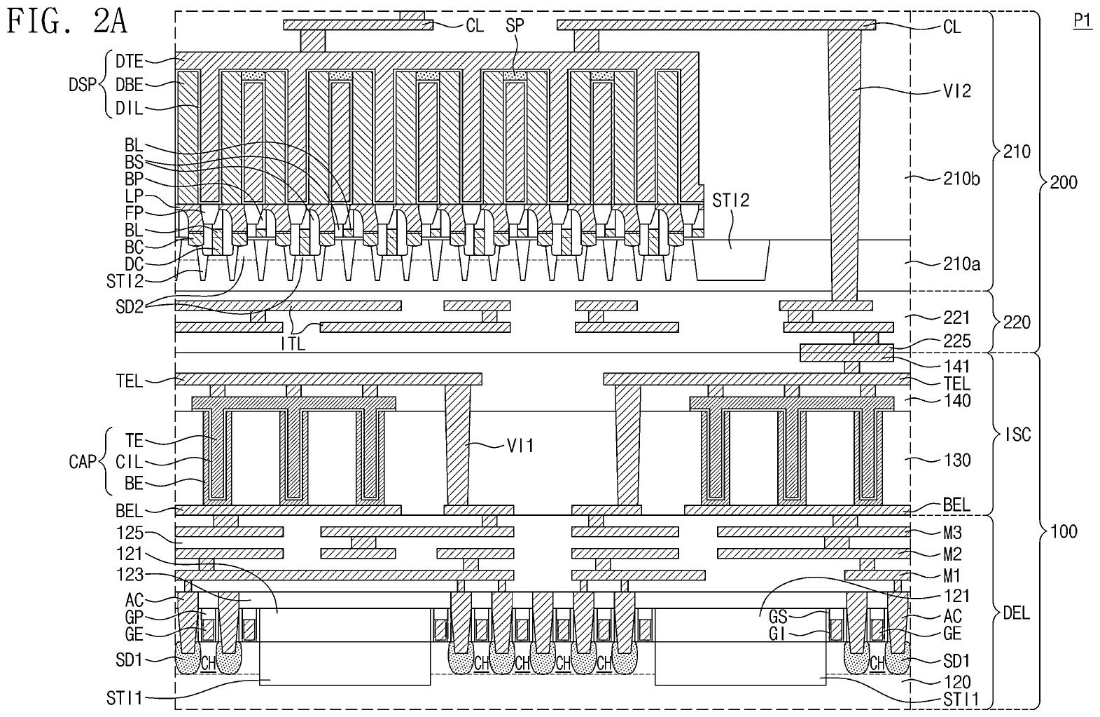

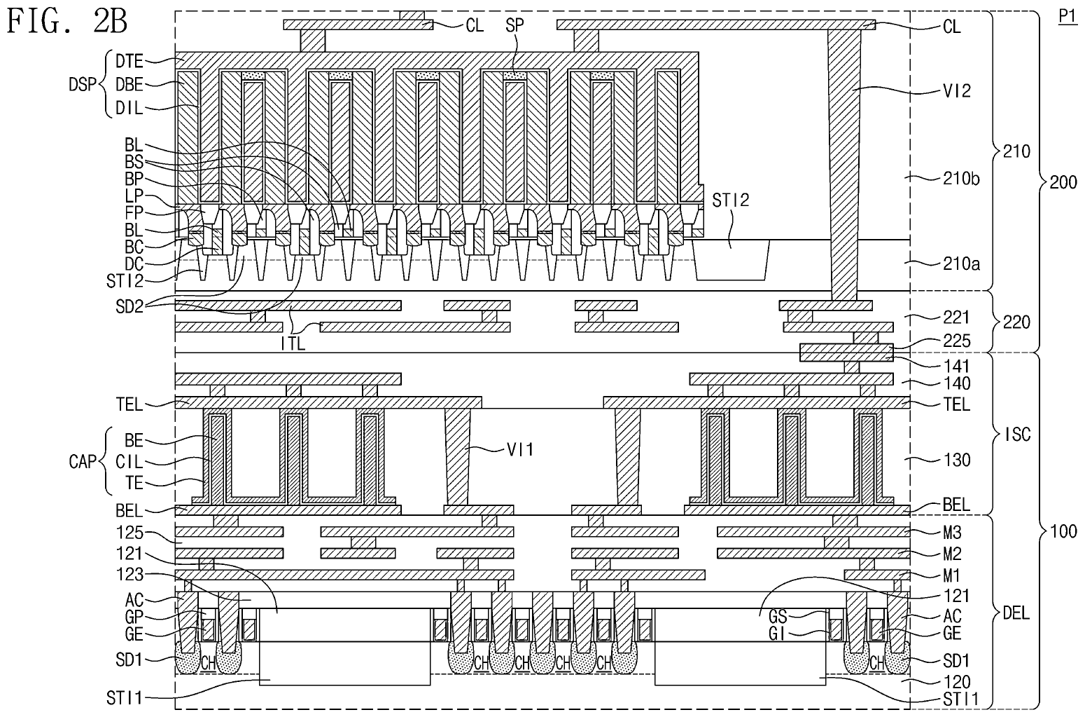

FIGS. 2A and 2B illustrate enlarged views of section P1 depicted in FIG. 1, partially showing a semiconductor package according to some embodiments of the present disclosure.

Referring to FIGS. 2A and 2B, the buffer chip 100 may include the device layer DEL and the capacitor layer ISC on the device layer DEL. The device layer DEL may include a first substrate 120, a plurality of transistors, and wiring patterns. For example, the first substrate 120 may be a compound semiconductor substrate or a semiconductor substrate including silicon, germanium, or silicon-germanium. According to an embodiment, the first substrate 120 may be a silicon substrate.

The first substrate 120 may be provided therein with first device isolation layers STI1 that define active regions. The first device isolation layers STI1 may be positioned in trenches that are formed by partially removing an upper portion of the first substrate 120. The first device isolation layers STI1 may be positioned between first source/drain patterns SD1 that are relatively spaced apart from each other as discussed below. For example, the first device isolation layers STI1 may include silicon oxide.

The plurality of transistors may include the first source/drain patterns SD1, channel patterns CH, and gate electrodes GE. The plurality of transistors may constitute an integrated circuit, and the integrated circuit may include a logic circuit.

The first source/drain patterns SD1 may be regions doped with p-type impurities. The first source/drain patterns SD1 may be epitaxial patterns formed by a selective epitaxial growth process. For example, the first source/drain patterns SD1 may have their top surfaces coplanar with top surfaces of the channel patterns CH, but embodiments of the present disclosure are not limited thereto.

The channel pattern CH may be positioned between neighboring ones of the first source/drain patterns SD1. The channel patterns CH may include a semiconductor material, such as silicon. For example, the channel patterns CH may have a shape that protrudes in the vertical direction from the first substrate 120. In this case, the plurality of transistors may have a fin field effect transistor (FinFET) structure. Embodiments of the present disclosure, however, are not limited thereto, and each of the channel patterns CH may include a plurality of semiconductor patterns that are sequentially stacked. The plurality of semiconductor patterns may be provided therebetween with portions of a gate electrode GE which will be discussed below. In this case, the plurality of transistors may have a multi-bridge channel field effect transistor (MBCFET) structure.

Gate electrodes GE may be disposed on the channel patterns CH. The gate electrodes GE may be spaced apart from each other in the horizontal direction. The gate electrodes GE may vertically overlap corresponding ones of the channel patterns CH.

Gate capping patterns GP may be provided on the gate electrodes GE. The gate capping patterns GP may be positioned between a pair of gate spaces GS which will be discussed below, while vertically overlapping the gate electrodes GE. For example, the gate capping patterns GP may include at least one from among SiON, SiCN, SiCON, and SiN.

Gate spacers GS may be provided on opposite lateral surfaces of each of the gate electrodes GE. The gate spacers GS may have their top surfaces located at a higher level than a level of top surfaces of the gate electrodes GE. The top surfaces of the gate spacers GS may be coplanar with top surfaces of the gate capping patterns GP. For example, the gate spacers GS may include at least one from among SiCN, SiCON, and SiN. Alternatively, the gate spacers GS may include a multi-layer formed of at least two from among SiCN, SiCON, and SiN.

Gate dielectric layers GI may be provided between the gate electrodes GE and the gate spacers GS and between the gate electrodes GE and the channel patterns CH. The gate dielectric layers GI may be in contact with corresponding ones of the gate electrodes GE. The gate dielectric layers GI may cover bottom and lateral surfaces of the gate electrodes GE in contact therewith. For example, the gate dielectric layers GI may include one or more of a silicon oxide layer, a silicon oxynitride layer, and a high-k dielectric layer. Alternatively, the gate dielectric layers GI may have a structure in which a silicon oxide layer and a high-k dielectric layer are stacked.

A first interlayer dielectric layer 121 may be provided on the first substrate 120. The first interlayer dielectric layer 121 may cover the first source/drain patterns SD1 and the first device isolation layers STI1. The first interlayer dielectric layer 121 may have a top surface coplanar with top surfaces of the gate capping patterns GP and top surfaces of the gate spacers GS.

A second interlayer dielectric layer 123 may be provided on the first interlayer dielectric layer 121. The second interlayer dielectric layer 123 may cover the first interlayer dielectric layer 121, the gate capping patterns GP, and the gate spacers GS. For example, the first interlayer dielectric layer 121 and the second interlayer dielectric layer 123 may include the same dielectric material, but embodiments of the present disclosure are not limited thereto.

Active contacts AC may be provided to penetrate the first interlayer dielectric layer 121 and the second interlayer dielectric layer 123. The active contacts AC may be connected to the first source/drain patterns SD1. The active contacts AC may have their bottom surfaces positioned in the first source/drain patterns SD1. Each of the active contacts AC may be disposed between the gate electrodes GE that are adjacent to each other. For example, the gate capping patterns GP and the gate spacers GS may be used to form the active contacts AC in a self-alignment manner.

The second interlayer dielectric layer 123 may be provided with wiring patterns therein. The wiring patterns may include first metal patterns M1, second metal patterns M2, and third metal patterns M3. The first metal patterns M1, the second metal patterns M2, and the third metal patterns M3 may be sequentially stacked. For example, the second metal pattern M2 may be positioned on the first metal pattern M1, and the third metal pattern M3 may be positioned on the second metal pattern M2. Therefore, the first metal patterns M1, the second metal patterns M2, and the third metal patterns M3 may be located at different levels.

Each of the first metal patterns M1, the second metal patterns M2, and the third metal patterns M3 may include lines and vias. The lines may extend in the horizontal direction. The vias may be positioned between and electrically connect to each other the lines that are adjacent to each other in the vertical direction. One or more of the vias may be connected to the active contacts AC and a lower electrode line BEL which will be discussed below.

A first wiring dielectric layer 125 may be provided on the second interlayer dielectric layer 123. The first wiring dielectric layer 125 may cover the wiring patterns. The first wiring dielectric layer 125 may surround the first metal patterns M1, the second metal patterns M2, and the third metal patterns M3. For example, the first wiring dielectric layer 125 may include silicon oxide, silicon nitride, and/or silicon oxynitride. Alternatively, the first wiring dielectric layer 125 may include a multiple layer including at least one from among silicon oxide, silicon nitride, and silicon oxynitride.

The capacitor layer ISC may be positioned on the device layer DEL. The capacitor layer ISC may include a lower electrode line BEL positioned on the first wiring dielectric layer 125 of the device layer DEL. The lower electrode line BEL may be connected to one or more of the vias of the wiring patterns. Thus, the lower electrode line BEL may be electrically connected to the device layer DEL.

The capacitor layer ISC may include a first dielectric pattern 130 positioned on the first wiring dielectric layer 125. The first dielectric pattern 130 may cover the lower electrode line BEL. The first dielectric pattern 130 may include a dielectric material. For example, the first dielectric pattern 130 may include tetraethylorthosilicate (TEOS).

The capacitor layer ISC may include a capacitor CAP that is positioned on the lower electrode line BEL and penetrates the first dielectric pattern 130. The capacitor CAP may be provided in plural, but embodiments of the present disclosure are not limited thereto. For example, the capacitor layer ISC may include at least one capacitor CAP. The capacitor CAP may include a lower electrode BE, an upper electrode TE, and a capacitor dielectric layer CIL.

According to the embodiment of FIG. 2A, the lower electrode BE may have a bottom part and a sidewall part that vertically extends from the bottom part to define an empty space. For example, the lower electrode BE may have a cylindrical shape. In this case, the capacitor dielectric layer CIL and the upper electrode TE may be positioned in the empty space of the lower electrode BE.

According to the embodiment of FIG. 2B, the lower electrode BE may have a pillar shape that vertically extends from the lower electrode line BEL. In this case, the capacitor dielectric layer CIL and the upper electrode TE may be positioned on a top surface and a lateral surface of the lower electrode BE.

The lower electrode BE may be provided in plural. In this case, the lower electrode line BEL and an upper electrode line TEL which will be discussed below may each have a plate shape. The lower electrodes BE may be arranged in a zigzag fashion or a honeycomb shape on the lower electrode line BEL. The lower electrodes BE may increase in both diameter and integration.

The capacitor dielectric layer CIL and the upper electrode TE may be sequentially positioned on the lower electrode BE. The capacitor dielectric layer CIL may be positioned between the lower electrode BE and the upper electrode TE. The capacitor dielectric layer CIL may have a uniform thickness that covers the lower electrode BE. The thickness of the capacitor dielectric layer CIL may be less than a thickness of the lower electrode BE and a thickness of the upper electrode TE. For example, the capacitor dielectric layer CIL may be a single layer or a combination thereof including at least one metal oxide, such as HfO₂, ZrO₂, Al₂O₃, La₂O₃, Ta₂O₃, and TiO₂, and/or perovskite dielectric materials, such as SrTiO₃ (STO), (Ba,Sr) TiO₃ (BST), BaTiO₃, PZT, and PLZT.

The upper electrode TE may be positioned on the capacitor dielectric layer CIL. When the lower electrode BE is provided in plural, one upper electrode TE may cover the lower electrodes BE. For example, the lower electrodes BE may share one upper electrode TE. The upper electrode TE and the lower electrode BE may include one or more of a refractory metal layer including cobalt, titanium, nickel, tungsten, or molybdenum and a metal nitride layer such as a titanium nitride (TiN) layer, a titanium silicon nitride (TiSiN) layer, a titanium aluminum nitride (TiAIN) layer, a tantalum nitride (TaN) layer, tantalum silicon nitride (TaSiN) layer, tantalum aluminum nitride (TaAIN) layer, or a tungsten nitride (WN) layer.

The capacitor layer ISC may include a second dielectric pattern 140 positioned on the first dielectric pattern 130. On the first dielectric pattern 130, the second dielectric pattern 140 may cover the capacitor CAP. The second dielectric pattern 140 may include a dielectric material. For example, the second dielectric pattern 140 may include the same dielectric material as the dielectric material of the first dielectric pattern 130, but embodiments the present disclosure are not limited thereto.

The capacitor layer ISC may include an upper electrode line TEL positioned on the capacitor CAP. The upper electrode line TEL may be positioned in the second dielectric pattern 140. The upper electrode line TEL may be connected to the upper electrode TE through a via as shown in FIG. 2A or may be in direct contact with and connected to the upper electrode TE as shown in FIG. 2B. The upper electrode line TEL may be electrically connected to the device layer DEL through a first via VI1 that penetrates the first dielectric pattern 130.

The capacitor layer ISC may include an upper pad 141 positioned at a top surface of the capacitor layer ISC. The upper pad 141 may be exposed by the second dielectric pattern 140. For example, a top surface of the upper pad 141 may be coplanar with the top surface of the second dielectric pattern 140. As the upper pad 141 is connected to the upper electrode line TEL, the upper pad 141 may be electrically connected through the upper electrode line TEL to the capacitor CAP.

An increase in area of the lower electrode BE may cause an increase in capacitance of the capacitor CAP of the capacitor layer ISC. For example, the capacitance of the capacitor CAP may be changed depending on a vertical length of the lower electrode BE of the capacitor CAP. The vertical length of the lower electrode BE may be substantially the same as a thickness of the first dielectric pattern 130. When the first dielectric pattern 130 includes tetraethylorthosilicate (TEOS), the thickness of the first dielectric pattern 130 may be easily formed and controlled.

The capacitor layer ISC including the first dielectric pattern 130 may have an appropriate thickness for achieving compactness of a semiconductor package and capacitance of the capacitor CAP. For example, the thickness of the capacitor layer ISC may range from about 1,500 μm to about 2,500 μm.

A first semiconductor chip 200 may be provided on the buffer chip 100. The first semiconductor chip 200 may include a first wiring layer 220 and a first core layer 210 on the first wiring layer 220. The buffer chip 100 and the first semiconductor chip 200 may be in contact with each other.

The first wiring layer 220 may be positioned on the capacitor layer ISC. The first wiring layer 220 may include interlayer lines ITL, a second wiring dielectric layer 221, and a first front pad 225. The first front pad 225 may be positioned at a bottom surface of the first wiring layer 220. The first front pad 225 may be exposed by the bottom surface of the first wiring layer 220. The first front pad 225 may be in contact with the upper pad 141 of the capacitor layer ISC. The first front pad 225 and the upper pad 141 may vertically overlap each other and may have substantially the same width. For example, a hybrid bonding may be achieved between the first front pad 225 and the upper pad 141. Therefore, the buffer chip 100 and the first semiconductor chip 200 may be electrically connected to each other.

The interlayer lines ITL may be positioned in the second wiring dielectric layer 221. The interlayer lines ITL may include wiring lines that extend in the horizontal direction and vias between the wiring lines that are adjacent to each other in the vertical direction. The interlayer lines ITL may be connected to the first front pad 225. On the capacitor layer ISC, the second wiring dielectric layer 221 may surround the interlayer lines ITL. The second wiring dielectric layer 221 may cover a top surface and a lateral surface of the first front pad 225. For example, the second wiring dielectric layer 221 may include one or more from among silicon oxide, silicon nitride, and silicon oxynitride. Alternatively, the second wiring dielectric layer 221 may include multiple layers including at least one from among silicon oxide, silicon nitride, and silicon oxynitride.

The first core layer 210 may include a second substrate 210a, a semiconductor device formed on the second substrate 210a, and a third interlayer dielectric layer 210b on the second substrate 210a and covering the semiconductor device. For example, the semiconductor device may be a memory device.

The second substrate 210a may be positioned on the first wiring layer 220. For example, the second substrate 210a may be a compound semiconductor substrate or a semiconductor substrate including silicon, germanium, or silicon-germanium. Like the first substrate 120, the second substrate 210a may be a silicon substrate.

The second substrate 210a may be provided therein with second device isolation layers STI2 that define active regions. The second device isolation layers STI2 may be positioned in trenches formed by partially removing an upper portion of the second substrate 210a. The second device isolation layers STI2 may be positioned between second source/drain patterns SD2 which will be discussed below. For example, the second device isolation layers STI2 may include silicon oxide.

The semiconductor device may include the second source/drain patterns SD2, a word line, bit lines BL, and data storage patterns DSP. The second source/drain patterns SD2 may be positioned in the second substrate 210a. The second source/drain patterns SD2 may be impurity doped regions in the second substrate 210a. For example, the second source/drain patterns SD2 may be n-type impurity doped regions. One of the second source/drain patterns SD2 may correspond to a source region of the semiconductor device, and another of the second source/drain patterns SD2 may correspond to a drain region of the semiconductor device.

Bit-line contacts DC, the bit lines BL, and bit-line capping patterns BP may be sequentially provided on one or more of the second source/drain patterns SD2. The bit-line contacts DC may electrically connect the bit lines BL to some of the second source/drain patterns SD2. For example, the bit-line contacts DC may include impurity-doped polysilicon or impurity-undoped polysilicon. The bit lines BL may include at least one from among, for example, metal (e.g., tungsten, titanium, and tantalum) and conductive metal nitride (e.g., titanium nitride, tantalum nitride, and tungsten nitride). The bit-line capping patterns BP may include a dielectric material.

Bit-line spacers BS may be provided on opposite lateral surfaces of the bit-line contacts DC, the bit lines BL, and the bit-line capping patterns BP. A pair of bit-line spacers BS may cover lateral surfaces of the bit-line contacts DC, the bit lines BL, and bit-line capping patterns BP that vertically overlap each other. The bit-line spacers BS may include one or more from among silicon oxide, silicon nitride, silicon oxynitride, and air gaps. Alternatively, the bit-line spacers BS may be formed of multiple layers including different dielectric materials.

Storage node contacts BC may be provided between the bit lines BL that are adjacent to each other in the horizontal direction. The storage node contacts BC may be spaced apart from each other in the horizontal direction. The storage node contacts BC may be connected to the second source/drain patterns SD2 that are not connected to the bit-line contacts DC. The storage node contacts BC may include, for example, impurity-doped polysilicon.

Landing pads LP may be provided on the storage node contacts BC. The landing pads LP may be spaced apart from each other in the horizontal direction. The landing pads LP may be connected to corresponding ones of the storage node contacts BC. The landing pad LP may have lower portions that vertically overlap the storage node contact BC. The landing pads LP may have upper portions that are shifted in the horizontal direction from the lower portions thereof. The upper portions of the landing pads LP may be positioned on the bit-line capping patterns BP.

Filling patterns FP may be provided between the landing pads LP that are adjacent to each other in the horizontal direction. The filling patterns FP may surround lateral surfaces of the landing pads LP. For example, the filling patterns FP may include at least one from among silicon nitride, silicon oxide, silicon oxynitride, and combinations thereof. Alternatively, the filling patterns FP may include an empty space (or air gap) including an air layer.

The data storage patterns DSP may be provided on the landing pads LP. The data storage patterns DSP may be spaced apart from each other in the horizontal direction. The data storage patterns DSP may be connected to corresponding ones of the landing pads LP. The data storage patterns DSP may include data lower electrodes DBE, a data dielectric layer DIL, and a data upper electrode DTE. The data dielectric layer DIL may be positioned between the data lower electrode DBE and the data upper electrode DTE, while having a uniform thickness. Support patterns SP may be provided between the data lower electrodes DBE that are adjacent to each other in the horizontal direction.

For example, the data storage patterns DSP may include a capacitor. In this case, the semiconductor device may be a dynamic random access memory (DRAM). Embodiments of the present disclosure, however, are not limited thereto, and the data storage patterns DSP may include a magnetic tunnel junction pattern. In this case, the semiconductor device may be a magnetic random access memory (MRAM). According to some embodiments, the data storage patterns DSP may include a phase change material or a variable resistance material. In this case, the semiconductor device may be a phase change random access memory (PRAM) or a resistive random access memory (ReRAM).

Memory lines CL may be provided on the data upper electrode DTE of the data storage patterns DSP. The memory lines CL may be connected to the data upper electrode DTE. One of the memory lines CL may be electrically connected through a second via VI2 to the first wiring layer 220. Thus, the semiconductor device of the first semiconductor chip 200 may be electrically connected to the capacitor CAP of the buffer chip 100.

Referring back to FIGS. 1, 2A, and 2B, a semiconductor package according to some embodiments of the present disclosure may include the capacitor layer ISC between the first semiconductor chip 200 and the device layer DEL of the buffer chip 100. The capacitor layer ISC may include at least one capacitor CAP, and the capacitor CAP may be electrically connected to a lowermost one of the first semiconductor chips 200. In addition, the capacitor CAP may vertically overlap the second semiconductor chip 300 and the first semiconductor chips 200 on the buffer chip 100. The capacitor CAP may be horizontally spaced apart from the molding layer 400 on the buffer chip 100. For example, the capacitor CAP of the capacitor layer ISC may be positioned adjacent to the first chips 200 and the second semiconductor chip 300. Thus, a semiconductor package according to an embodiment of the present disclosure may have power delivery efficiency and signal delivery efficiency greater than those of a semiconductor package that uses a multi-layer ceramic capacitor (MLCC). Accordingly, a semiconductor package according to embodiments of the present disclosure may have improved electrical properties.

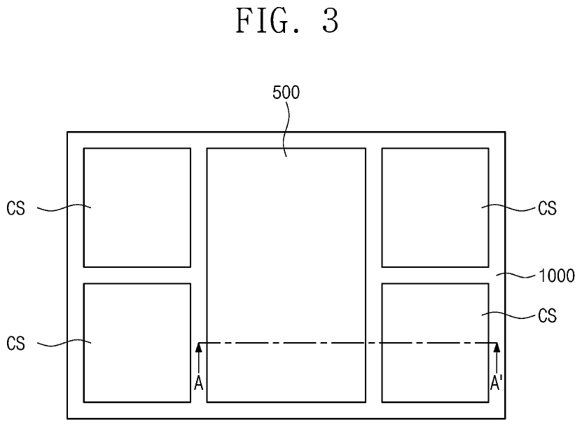

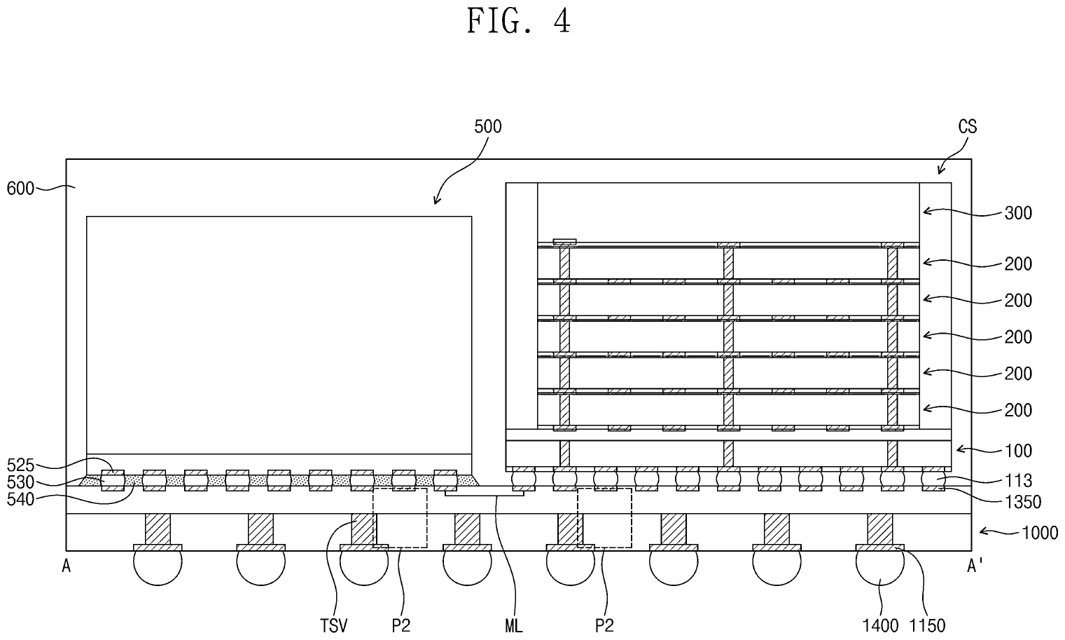

FIG. 3 illustrates a plan view showing a semiconductor package according to some embodiments of the present disclosure. FIG. 4 illustrates a cross-sectional view taken along line A-A′ of FIG. 3, showing a semiconductor package according to some embodiments of the present disclosure.

Referring to FIGS. 3 and 4, a semiconductor package according to some embodiments of the present disclosure may include an interposer substrate 1000, a third semiconductor chip 500, and a plurality of chip stacks CS.

Each of the chip stacks CS may include the first semiconductor chips 200 the second semiconductor chip 300, that are vertically stacked, of FIG. 1. The first semiconductor chips 200 and the second semiconductor chip 300 may each be a memory chip, such as dynamic random access memory (DRAM), static random access memory (SRAM), NAND Flash memory, or resistive random access memory (RRAM).

When viewed in a plan view, the third semiconductor chip 500 and the chip stacks CS may overlap the interposer substrate 1000. The chip stacks CS may be positioned at a side of opposite lateral surfaces of the third semiconductor chip 500 and spaced apart from the third semiconductor chip 500. For example, on the interposer substrate 1000, the chip stacks CS may be positioned adjacent to the third semiconductor chip 500.

The interposer substrate 1000 may include upper pads 1350, lower pads 1150, through vias TSV, and a metal line ML. The upper pads 1350 may be positioned at a top surface of the interposer substrate 1000 and may be spaced apart from each other. The lower pads 1150 may be positioned at a bottom surface of the interposer substrate 1000 and may be spaced apart from each other. The through vias TSV may be positioned in the interposer substrate 1000 and may electrically connect the lower pads 1150 to the upper pads 1350. The metal line ML may electrically connect the third semiconductor chip 500 to the chip stacks CS. For example, the interposer substrate 1000 may be a wafer-level die formed of a semiconductor such as silicon, but embodiments of the present disclosure are not limited thereto.

The interposer substrate 1000 may be provided with external connection terminals 1400 on the bottom surface thereof. The external connection terminals 1400 may be positioned on corresponding bottom surfaces of the lower pads 1150. The external connection terminals 1400 may be coupled to the lower pads 1150 and may be electrically connected through the lower pads 1150 to the upper pads 1350. For example, the external connection terminals 1400 may each be an alloy that includes at least one from among tin (Sn), silver (Ag), copper (Cu), nickel (Ni), bismuth (Bi), indium (In), antimony (Sb), and cerium (Ce).

The third semiconductor chip 500 may be mounted on the interposer substrate 1000. For example, the third semiconductor chip 500 may be a logic chip including a processor, such as a microelectromechanical system (MEMS) device, an optoelectronic device, a central processing unit (CPU), a graphic processing unit (GPU), a mobile application, or a digital signal processor (DSP).

The third semiconductor chip 500 may include chip pads 525. The chip pads 525 may be positioned at a bottom surface of the third semiconductor chip 500. The chip pads 525 may be exposed by the bottom surface of the third semiconductor chip 500. For example, the chip pads 525 may have their bottom surfaces coplanar with the bottom surface of the third semiconductor chip 500.

Chip terminals 530 may be provided between the third semiconductor chip 500 and the interposer substrate 1000. The chip terminals 530 may be positioned between and in contact with corresponding ones of the chip pads 525 of the third semiconductor chip 500 and corresponding ones of the upper pads 1350 of the interposer substrate 1000. Thus, the third semiconductor chip 500 may be electrically connected to the interposer substrate 1000. For example, the chip terminals 530 may each be an alloy that includes at least one from among silver (Ag), copper (Cu), nickel (Ni), bismuth (Bi), indium (In), antimony (Sb), and cerium (Ce).

The third semiconductor chip 500 and the interposer substrate 1000 may be provided therebetween with an underfill layer 540 that surrounds the chip terminals 530. The underfill layer 540 may surround lateral surfaces of the chip terminals 530. The underfill layer 540 may not cause the chip terminals 530 to be outwardly exposed. As the chip terminals 530 are protected against external impact, the semiconductor package may have improved reliability. For example, the underfill layer 540 may include a dielectric material.

The chip stacks CS may be spaced apart in the horizontal direction from the third semiconductor chip 500 and may be mounted on the interposer substrate 1000. The chip stacks CS may have a chip stack structure. Each of the chip stacks CS may include a buffer chip 100, a plurality of first semiconductor chips 200 stacked on the buffer chip 100, and a second semiconductor chip 300 on the first semiconductor chips 200. For example, each of the chip stacks CS may be substantially the same as the semiconductor package discussed with reference to FIGS. 1, 2A, and 2B. Therefore, the buffer chip 100 may include a device layer DEL and a capacitor layer ISC that includes at least one capacitor CAP on the device layer DEL.

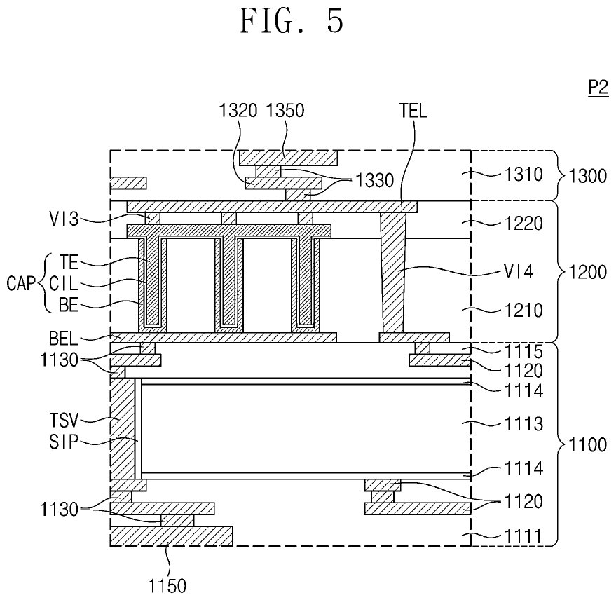

FIG. 5 illustrates an enlarged view of section P2 depicted in FIG. 4, partially showing a semiconductor package according to some embodiments of the present disclosure.

Referring to FIG. 5, the interposer substrate 1000 may include a lower wiring layer 1100, an upper wiring layer 1300 on the lower wiring layer 1100, and a capacitor layer 1200 between the lower wiring layer 1100 and the upper wiring layer 1300.

The lower wiring layer 1100 may include a lower pad 1150, lower wiring patterns (e.g., lower lines 1120 and lower vias 1130), through vias TSV, a silicon layer 1113, and lower dielectric layers (e.g., a first lower dielectric layer 1111 and a second lower dielectric layer 1115). The lower pad 1150 may be connected to the lower wiring patterns (e.g., the lower lines 1120 and the lower vias 1130). The lower pad 1150 may be positioned at a bottom surface of the lower wiring layer 1100. For example, the bottom surface of the lower wiring layer 1100 may correspond to the bottom surface of the interposer substrate 1000.

The lower dielectric layers may include a first lower dielectric layer 1111 and a second lower dielectric layer 1115 on the first lower dielectric layer 1111. The first lower dielectric layer 1111 may cover the lower pad 1150 and the lower wiring patterns (e.g., the lower lines 1120 and the lower vias 1130). The first lower dielectric layer 1111 may cover a top surface and a lateral surface of the lower pad 1150. The second lower dielectric layer 1115 may surround the lower wiring patterns (e.g., the lower lines 1120 and the lower vias 1130). The lower wiring patterns (e.g., the lower lines 1120 and the lower vias 1130) may be positioned in each of the first lower dielectric layer 1111 and the second lower dielectric layer 1115. For example, the first lower dielectric layer 1111 and the second lower dielectric layer 1115 may include one or more from among silicon oxide, silicon nitride, and silicon oxynitride. Alternatively, the first lower dielectric layer 1111 and the second lower dielectric layer 1115 may include multiple layers including at least one from among silicon oxide, silicon nitride, and silicon oxynitride.

The lower wiring patterns may include lower lines 1120 and lower vias 1130. The lower lines 1120 may extend in the horizontal direction. The lower lines 1120 may be spaced apart from each other in the vertical or horizontal direction. For example, the lower lines 1120 may be located at substantially the same level or at different levels. The lower vias 1130 may be positioned between the lower lines 1120 that are adjacent to each other in the vertical direction. The lower vias 1130 may electrically connect the lower lines 1120 to each other. One of the lower vias 1130 positioned in the first lower dielectric layer 1111 may be connected to the lower pad 1150. One of the lower vias 1130 positioned in the second lower dielectric layer 1115 may be connected to a lower electrode line BEL which will be discussed below.

The silicon layer 1113 may be positioned between the first lower dielectric layer 1111 and the second lower dielectric layer 1115, and the through via TSV may be provided in the silicon layer 1113. For example, the silicon layer 1113 and the through via TSV may be positioned between the first lower dielectric layer 1111 and the second lower dielectric layer 1115. The through via TSV may be connected to one of the lower lines 1120 of the first lower dielectric layer 1111 and to one of the lower vias 1130 of the second lower dielectric layer 1115. For example, the through vias TSV may electrically connect the lower wiring patterns (e.g., the lower lines 1120 and the lower vias 1130) in the first lower dielectric layer 1111 and the second lower dielectric layer 1115.

A plurality of dielectric layers 1114 may be provided between the silicon layer 1113 and the lower dielectric layers (e.g., the first lower dielectric layer 1111 and the second lower dielectric layer 1115). Dielectric layers 1114 may be positioned on a top surface and a bottom surface of the silicon layer 1113, respectively. A spacer dielectric pattern SIP may be provided in the silicon layer 1113 and may be positioned on a lateral surface of the through via TSV. The spacer dielectric pattern SIP may surround the lateral surface of the through via TSV. The dielectric layers 1114 and the spacer dielectric pattern SIP may electrically insulate the silicon layer 1113 from the through via TSV and the lower wiring patterns (e.g., the lower lines 1120 and the lower vias 1130).

The upper wiring layer 1300 may include an upper pad 1350, upper wiring patterns (e.g., upper lines 1320 and upper vias 1330), and an upper dielectric layer 1310. The upper pad 1350 may be connected to the upper wiring patterns (e.g., the upper lines 1320 and the upper vias 1330). The upper pad 1350 may be positioned at a top surface of the upper wiring layer 1300. For example, the top surface of the upper wiring layer 1300 may correspond to the upper surface of the interposer substrate 1000.

The upper wiring patterns may include upper lines 1320 and upper vias 1330. The upper lines 1320 may extend in the horizontal direction. The upper lines 1320 may be spaced apart from each other in the vertical or horizontal direction. For example, the upper lines 1320 may be located at substantially the same or different levels. The upper vias 1330 may be positioned between the upper lines 1320 that are adjacent to each other in the vertical direction. The upper vias 1330 may electrically connect the upper lines 1320 to each other. One or more of the upper vias 1330 may be connected to the upper pad 1350 and an upper electrode line TEL which will be discussed below.

The upper dielectric layer 1310 may cover the upper pad 1350 and the upper wiring patterns (e.g., the upper lines 1320 and the upper vias 1330). The upper dielectric layer 1310 may cover a bottom surface and a lateral surface of the upper pad 1350. The upper dielectric layer 1310 may surround the upper wiring patterns (e.g., the upper lines 1320 and the upper vias 1330). For example, the upper dielectric layer 1310 may include one or more from among silicon oxide, silicon nitride, and silicon oxynitride. Alternatively, the upper dielectric layer 1310 may include multiple layers including at least one from among silicon oxide, silicon nitride, and silicon oxynitride.

The capacitor layer 1200 may include a lower electrode line BEL, an upper electrode line TEL, a first dielectric pattern 1210, a second dielectric pattern 1220, and at least one capacitor CAP. The upper electrode line TEL may be positioned on the lower electrode line BEL, and the capacitor CAP may be positioned between the lower electrode line BEL and the upper electrode line TEL. The capacitor CAP may be connected to the lower electrode line BEL and the upper electrode line TEL. The lower electrode line BEL may be connected to one of the lower vias 1130, and the upper electrode line TEL may be connected through a fourth via VI4 to the lower wiring patterns (e.g., the lower lines 1120 and the lower vias 1130). For example, the lower electrode line BEL and the upper electrode line TEL may be electrically connected through the lower wiring patterns (e.g., the lower lines 1120 and the lower vias 1130) to the lower pad 1150. Thus, the capacitor CAP may be provided with a voltage through the external connection terminal 1400 of FIG. 4 connected to the lower pad 1150.

The capacitor CAP may penetrate the first dielectric pattern 1210. The capacitor CAP may include a lower electrode BE, an upper electrode TE, and a capacitor dielectric layer CIL between the lower electrode BE and the upper electrode TE. The lower electrode BE may be provided in plural, and the plurality of lower electrodes BE may be arranged in various shapes. The upper electrode TE may cover the lower electrode BE. The second dielectric pattern 1220 may be positioned on the first dielectric pattern 1210 and may cover the capacitor CAP. For example, the first dielectric pattern 1210 may include tetraethylorthosilicate (TEOS). The second dielectric pattern 1220 may include the same dielectric material as the dielectric material of the first dielectric pattern 1210, but embodiments of the present disclosure are not limited thereto.

Referring to FIGS. 4 and 5, one or more of the capacitor CAP of the interposer substrate 1000 may vertically overlap with the third semiconductor chip 500 and the chip stack CS. Because the one or more capacitor CAP is connected through the upper wiring patterns (e.g., the upper lines 1320 and the upper vias 1330) to the upper pad 1350, the one or more capacitor CAP may be electrically connected to the third semiconductor chip 500 and the chip stack CS. For example, the one or more capacitor CAP may be positioned adjacent to and electrically connected to the third semiconductor chip 500 and the chip stack CS. Thus, the third semiconductor chip 500 and the chip stack CS may increase in power delivery efficiency and signal delivery efficiency. Accordingly, a semiconductor package may have improved electrical properties.

According to an embodiment, the one or more capacitor CAP may vertically overlap at least one from the among third semiconductor chip 500 and the chip stack CS. For example, the one or more capacitor CAP may vertically overlap one or both of the third semiconductor chip 500 and the chip stack CS.

Referring to FIGS. 1 to 5, the capacitor layer 1200 of the interposer substrate 1000 may have substantially the same structure as the structure of the capacitor layer ISC of the buffer chip 100. In this description, the capacitor layer 1200 and the capacitor CAP of the interposer substrate 1000 may respectively correspond to a first capacitor layer and a first capacitor, and the capacitor layer ISC and the capacitor CAP of the buffer chip 100 may respectively correspond to a second capacitor layer and a second capacitor. For example, the first capacitor may vertically overlap the second capacitor. Alternatively, the first capacitor and the second capacitor may not vertically overlap each other, but may vertically overlap the first and semiconductor chips 200 and the second semiconductor chip 300.

A semiconductor package according to some embodiments of the present disclosure may include a buffer chip including a capacitor layer and semiconductor chips on the buffer chip. A capacitor of the capacitor layer may be electrically connected to and vertically overlap the semiconductor chips. As the capacitor of the capacitor layer is positioned adjacent to the semiconductor chips, the semiconductor chips may increase in power delivery efficiency and signal delivery efficiency. Accordingly, the semiconductor package may have improved electrical properties.

Although non-limiting example embodiments of the present disclosure been described in connection with the accompanying drawings, it will be understood to those skilled in the art that various changes and modifications may be made without departing from the technical spirit of the present disclosure. It therefore will be understood that the example embodiments described above are illustrative and are not limitative in all aspects.

What is claimed is:

1. A semiconductor package, comprising:
a buffer chip;
a plurality of semiconductor chips stacked on the buffer chip; and
a molding layer on the buffer chip and the plurality of semiconductor chips,
wherein the buffer chip comprises a device layer and a capacitor layer on the device layer,
wherein the device layer comprises a plurality of transistors that constitute logic circuits,
wherein the capacitor layer comprises a capacitor, and
wherein the plurality of semiconductor chips vertically overlap the capacitor.

2. The semiconductor package of claim 1, wherein the capacitor layer comprises:
a first dielectric pattern; and
a second dielectric pattern on the first dielectric pattern, and
wherein the capacitor comprises:
a lower electrode that penetrates the first dielectric pattern;
an upper electrode on the lower electrode; and
a capacitor dielectric layer between the lower electrode and the upper electrode.

3. The semiconductor package of claim 2, wherein the first dielectric pattern comprises tetraethylorthosilicate (TEOS).

4. The semiconductor package of claim 1, where a lowermost one of the plurality of semiconductor chips is in contact with the capacitor layer of the buffer chip.

5. The semiconductor package of claim 1, wherein the capacitor is horizontally spaced apart from the molding layer.

6. The semiconductor package of claim 1, wherein the capacitor layer further comprises a lower electrode line and an upper electrode line on the lower electrode line,
wherein the capacitor is between the lower electrode line and the upper electrode line.

7. The semiconductor package of claim 1, wherein each of the plurality of semiconductor chips comprises:
a circuit layer comprising a front pad; and
a core layer comprising a semiconductor device on the circuit layer.

8. The semiconductor package of claim 7, wherein the capacitor layer comprises an upper pad connected to the capacitor,
wherein the upper pad is connected to the front pad of a lowermost one of the plurality of semiconductor chips.

9. The semiconductor package of claim 1, wherein
a width of each of the plurality of semiconductor chips is the same as each other, and
a width of the buffer chip is greater than the width of the plurality of semiconductor chips.

10. The semiconductor package of claim 1, wherein a thickness of the capacitor layer is in a range of 1,500 μm to 2,500 μm.

11. A semiconductor package, comprising:
a buffer chip that comprises a device layer and a capacitor layer on the device layer; and
a memory chip that comprises a wiring layer and a core layer on the wiring layer,
wherein the device layer comprises a plurality of transistors that constitute a logic circuit,
wherein the capacitor layer comprises a capacitor and an upper pad,
wherein the wiring layer comprises a front pad connected to the upper pad,
wherein the core layer comprises a memory device electrically connected to the capacitor through the upper pad and the front pad, and
wherein the capacitor vertically overlaps with the memory chip.

12. The semiconductor package of claim 11, wherein the memory device comprises a dynamic random access memory (DRAM).

13. The semiconductor package of claim 11, wherein
the capacitor layer and the wiring layer are in contact with each other, and
the upper pad and the front pad are in contact with each other.

14. The semiconductor package of claim 11, wherein the capacitor comprises:
a plurality of lower electrodes;
an upper electrode that is on the plurality of lower electrodes; and
a capacitor dielectric layer between the upper electrode and the plurality of lower electrodes.

15. The semiconductor package of claim 11, wherein the capacitor layer comprises:
a first dielectric pattern through which the capacitor penetrates; and
a second dielectric pattern on the first dielectric pattern,
wherein the first dielectric pattern comprises tetraethylorthosilicate (TEOS).

16. A semiconductor package, comprising:
an interposer substrate;
a logic chip on the interposer substrate; and
at least one chip stack on the interposer substrate and spaced apart from the logic chip,
wherein the interposer substrate comprises:
a lower wiring layer that comprises a plurality of lower pads and a plurality of lower wiring patterns;
an upper wiring layer that comprises a plurality of upper pads and a plurality of upper wiring patterns; and
a first capacitor layer between the lower wiring layer and the upper wiring layer,
wherein the first capacitor layer comprises at least one first capacitor,
wherein the at least one first capacitor vertically overlaps at least one from among the logic chip and the at least one chip stack, and
wherein the at least one first capacitor is electrically connected through the plurality of upper pads and the plurality of upper wiring patterns to at least one from among the logic chip and the at least one chip stack.

17. The semiconductor package of claim 16, wherein each of the at least one chip stack comprises:
a buffer chip; and
a plurality of memory chips stacked on the buffer chip,
wherein the buffer chip comprises a device layer and a second capacitor layer on the device layer,
wherein the second capacitor layer comprises a second capacitor, and
wherein the plurality of memory chips vertically overlap the second capacitor.

18. The semiconductor package of claim 17, wherein the second capacitor layer comprises:
a first dielectric pattern through which the second capacitor penetrates; and
a second dielectric pattern that covers the second capacitor,
wherein the first dielectric pattern comprises tetraethylorthosilicate (TEOS).

19. The semiconductor package of claim 16, further comprising external connection terminals that are correspondingly connected to the plurality of lower pads of the lower wiring layer,
wherein the external connection terminals are electrically connected to the at least one first capacitor.

20. The semiconductor package of claim 16, wherein the at least one chip stack is a plurality of chip stacks that are on the interposer substrate.
